(19) United States
(12) Patent Application Publication
(10) Pub. No.: US 2010/0206628 A1
(43) Pub. Date: Aug. 19, 2010

(54) TRANSPARENT ELECTROMAGNETIC WAVE SHIELD MEMBER AND METHOD FOR MANUFACTURING THE SAME

(75) Inventors: Yoshitaka Matsui, Shiga (JP); Masaaki Kotoura, Shiga (JP); Osamu Watanabe, Shiga (JP); Tadashi Yoshioka, Shiga (JP); Keitaro Sakamoto, Shiga (JP)

Correspondence Address: PILLSBURY WINTHROP SHAW PITTMAN, LLP, P.O. BOX 10500, MCLEAN, VA, 22102, US

(73) Assignee: TORAY INDUSTRIES, INC., Tokyo (JP)

(21) Appl. No.: 12/440,016

(22) PCT Filed: Sep. 4, 2007
(86) PCT No.: PCT/JP2007/067159

§ 371 Date: Aug. 24, 2009

(30) Foreign Application Priority Data
Sep. 4, 2006 (JP) 2006-238604
Sep. 27, 2006 (JP) 2006-261937

(51) Int. Cl. H05K 9/00; B05D 5/12; C23C 14/14; C23C 14/34; B23K 26/00

(52) U.S. Cl. 174/389; 427/109; 427/531; 204/192.1; 219/121.85

(57) ABSTRACT

The present invention aims to provide a transparent electromagnetic wave shield member, which is free from a moirè phenomenon which could not be solved by the prior art, and in which an excellent electromagnetic wave shielding properties and a sufficient total light transmittance based on an appropriate network structure are compatible, and a method for manufacturing the same.

The transparent electromagnetic wave shield member of the present invention is a transparent electromagnetic wave shield member in which a metal layer of an electroconductive metal network structure having a geometrical shape is formed on a transparent substrate, and which is characterized in that a spacing of said network structure is 200 μm or less, an opening ratio of the network structure is 84% or more, and in addition, a thickness of the electroconductive metal layer is 2 μm or less.

Furthermore, the method for manufacturing such transparent electromagnetic wave shield member is a method for manufacturing a transparent electromagnetic wave shield member in which a metal layer of a network structure having a geometrical shape is formed on a transparent substrate, which is characterized in that a metal layer of a thickness of 2 μm or less is provided on a transparent substrate and the metal layer is removed by laser abrasion to form a metal layer of a network structure having a spacing of the network structure of 200 μm or less, and in addition, an opening ratio of the network structure of 84% or more.

### TECHNICAL FIELD

The present invention relates to a transparent electromagnetic wave shield member capable of fluoroscopy, which is used for image displaying parts such as plasma display panel (PDP) or cathode ray tube (CRT) which are electric products generating electromagnetic wave, and a method for manufacturing the same, and in addition, a filter and a display using the same.

### BACKGROUND ART

In recent years, regulations relating to electromagnetic wave generated from electric products have been strengthened because of its radio frequency interference to various precision instruments, measuring instruments and digital instruments or influence to human body. For that reason, discharge of the electromagnetic wave is regulated by law, for example, there is a regulation by VCCI (Voluntary Control Council for Interference by data processing equipment electronic office machine). Therefore, in PDP which discharges especially a strong electromagnetic wave to outside the device from the image displaying portion, the electromagnetic wave is shielded such that the above-mentioned regulation can be observed by directly adhering a transparent electromagnetic wave shield sheet to the image displaying portion as a front filter together with a sheet having other functions such as antireflection or near infrared ray shield, or adhering it to a transparent substrate such as glass or plastic for front filter and putting the front filter to the image displaying portion.

As this transparent electromagnetic wave shield sheet, conventionally, a sheet in which a patterned electroconductive metal layer is provided on a transparent substrate by employing a photolithography method in which, after laminating a metal layer such as copper foil on a transparent substrate via an adhesive layer, a resist film is put and exposure, development, etching and resist peeling are carried out, is proposed (Patent reference 1).

Furthermore, as other methods for providing a patterned electroconductive metal layer on a transparent substrate, a method in which an etching resist pattern is formed by a screen printing method or an offset printing method, and then an electroconductive metal layer is etched, and finally, the resist is peeled off (Patent reference 2 and Patent reference 3).

However, in the photolithography method in which the transparent electromagnetic wave shield sheet is manufactured by using an electroconductive metal layer laminated on a transparent substrate, a lattice-like electroconductive metal layer (copper foil layer) of the substrate has a network structure of a large regular spacing, and in addition, since there is a thickening in intersection portion of the network, there is a problem that a moirè phenomenon is generated.

The moirè phenomenon is, “a striped mottle generated when somethings having geometrically and regularly distributed dots or lines are superposed, and in the Kojien, there is a description that it is “a stripe patterned mottle generated when somethings having geometrically and regularly distributed dots or lines are superposed. It may arise when a halftone plate is reproduced from a halftone print as an original, and in case of a plasma display, a stripe pattern-like pattern is generated in its picture. This is because, in cases where a regular pattern such as of lattice-like is provided to an electromagnetic wave shield substrate to be provided in front of the display, due to an interaction with a regular lattice-like partition or the like which partitions pixels of the respective RGB colors of a display back panel, said moirè phenomenon generates. And, in cases where a regular pattern such as of lattice-like is provided to the electromagnetic wave shield substrate, there is a problem that, as the line width of this lattice becomes broader, this moirè phenomenon may generate more easily.

Furthermore, the process of photolithography is complicated and long, i.e., it is not a satisfactory method for the commercial needs of cost reduction.

Whereas, in order to make the electromagnetic wave shielding properties and visibility of the display picture compatible, a method is proposed that a black color resist layer is laminated on the patterned electroconductive metal layer, and said black color resist is left without peeling off (Patent reference 4), but after all, this also depends on a photolithography method, its process is complicated and long, i.e., it could not be said to be a satisfactory method for the commercial needs of cost reduction.

On the other hand, a method of forming an etching pattern of the transparent electromagnetic wave shield sheet by screen printing or offset printing is possible by a simple apparatus and a simple process, and in addition, it is possible to suppress glaring appearance by forming a black resin layer directly on the electroconductive metal layer having a metallic glare which may impair contrast performance. For that reason, it can be said to be a process which can sufficiently reply to the commercial needs of cost reduction. However, in these printing methods, it was difficult to print a high precision line width, and it was difficult to form a fine line pattern of 20 μm or less which is preferable for non-visibility of network pattern, and a moirè phenomenon was likely to generate on the display picture. And, there remained a problem to be solved in the obtained electromagnetic wave shield member in view point of transparency.

Furthermore, a method for manufacturing a transparent electromagnetic wave shield by making a network structure with an electroconductive fiber is proposed (Patent reference 5). However, since the electromagnetic wave shield member manufactured by this method has a thick line diameter of the electroconductive fiber, in cases where a sufficient shielding performance was demanded, there was a defect that an opening ratio decreases and visibility of picture decreases.

Furthermore, a method is proposed in which a network pattern is formed by printing an electroless plating catalyst on a transparent film and, successively, an electromagnetic wave shield is made by carrying out an electroless plating treatment (Patent reference 6). In this method, since the catalyst layer for the electroless plating is prepared by printing, it was difficult to narrow line width of the network and the line width of the network obtained after the plating was wide as 25 to 30 μm, and it was difficult to achieve an opening ratio for obtaining sufficient visibility.

Furthermore, a method is proposed in which a network pattern is drawn by coating silver salt which is a photosensitive material on a film and subjected to an exposure by ultraviolet ray through a mask pattern, to prepare a network pattern on a transparent support (Patent reference 7), but it has a defect that the process is complicated. And, it is difficult to obtain a sufficient shielding performance by the prepared silver salt network only, and since it is necessary, after the network pattern is prepared, to thicken the electroconductive layer by plating, it has a defect that the process becomes more complicated.

Patent reference 1: Publication of JP Patent No. 3388682
Patent reference 2: JP2000-315890A
Patent reference 3: JP2000-323889A
Patent reference 4: JP-H9-293989A
Patent reference 5: JP2005-311189A
Patent reference 6: JP2002-38095A
Patent reference 7: JP2006-12935A
Patent reference 8: JP2000-223886A

### DISCLOSURE OF THE INVENTION

### Problem to be Solved by the Invention

The object of the present invention is to provide a transparent electromagnetic wave shield member in which the above-mentioned defect is solved, a generation of moirè phenomenon is more prevented compared to the prior art, an excellent electromagnetic wave shielding properties and a sufficient total light transmittance based on an appropriate network structure are compatible, and a method for manufacturing the same. And the purpose of more preferable embodiment of the present invention is to provide a transparent electromagnetic wave shield member which does not impair visibility when fixed to a display, and a method for manufacturing the same.

### Means for Solving the Problem

The present invention employs the following means to solve the above-mentioned problem. That is, the present invention is the following (1) to (4) or the like.

(1) A method for manufacturing a transparent electromagnetic wave shield member in which a metal layer of a network structure having a geometrical shape is formed on a transparent substrate,
which is a method for manufacturing of a transparent electromagnetic wave shield member comprising a step for providing a metal layer of a thickness of 2 μm or less, and a step for removing said metal layer by a laser abrasion, to form a metal layer of a network structure having a spacing of the network structure of 200 μm or less, and in addition, an opening ratio of the network structure of 84% or more.
(2) A method for manufacturing a transparent electromagnetic wave shield member described in (1), comprising a step of forming a metal oxide layer on at least one surface side of the metal layer.
(3) A transparent electromagnetic wave shield member in which a metal layer of a network structure having a geometrical shape is formed on a transparent substrate,
which is a transparent electromagnetic wave shield member of which spacing of the network structure is 200 μm or less, an opening ratio of the network structure is 84% or more, and in addition, a thickness of the metal layer is 2 μm or less.
(4) A transparent electromagnetic wave shield member described in (3), comprising the metal layer formed in the network structure having the geometrical shape on the transparent substrate and a first metal oxide layer of a thickness of 0.01 to 0.1 μm provided on at least one surface side of the metal layer.

### Effect of the Invention

By the present invention, it is possible to obtain a transparent electromagnetic wave shield member, which is free from a moirè phenomenon, and in which an excellent electromagnetic wave shielding properties and a sufficient total light transmittance based on an appropriate network structure are compatible. And, by the preferable embodiments of the present invention, a transparent electromagnetic wave shield member of which image degradation is more prevented can be obtained.

### BRIEF EXPLANATION OF THE DRAWINGS

FIG. 1 An example of schematic cross sectional view of a transparent electromagnetic wave shield member of the present invention.

FIG. 2 An example of schematic cross sectional view of a transparent electromagnetic wave shield member of the present invention.

FIG. 3 An example of schematic cross sectional view of a transparent electromagnetic wave shield member of the present invention.

FIG. 4 A schematic cross sectional view which explains the manufacturing process of a transparent electromagnetic wave shield member of the present invention.

### EXPLANATION OF REFERENCES

1: transparent substrate
2: metal layer
3: adhesive layer
4: metal oxide layer
5: second metal oxide layer

### BEST MODE FOR CARRYING OUT THE INVENTION

The inventors studied hard on the above-mentioned problem, that is, a transparent electromagnetic wave shield member, which is free from a moirè phenomenon which could not be solved by the prior art, and in which an excellent electromagnetic wave shielding properties and a sufficient total light transmittance based on an appropriate network structure are compatible, and when spacing of the network structure of the transparent electromagnetic wave shield member was narrowed, and in addition, line width was decreased, the above-mentioned problem was solved excellently, and found that it is possible to effectively achieve a sufficient shielding performance with a high opening ratio, and in addition, without a moirè problem, and accomplished the present invention. And, when such a network structure is formed to the electromagnetic wave shield member of the present invention, it was found that it is especially effective to employ a laser abrasion. In the following, with reference to FIGS. 1 to 4, embodiments for carrying out the present invention are explained.

As a material of the transparent substrate 1 which constitutes the transparent electromagnetic wave shield member of the present invention, it is not especially limited to such as glass or plastics, but in view of handling and in view of flexibility which is required at manufacturing and processing in a wound configuration, plastics film is preferable.

As such plastics films, for example, polyester-based resins such as polyethylene terephthalate (hereafter, PET) or polyethylene naphthalate, acryl-based resin, polycarbonate resin, or polyolefin-based resins such as polypropylene, polyethylene, polybutene or polymethyl pentene, or cellulose-based resins such as triacetyl cellulose or diacetyl cellulose, polyvinyl chloride-based resins, polyamide-based resins, polystyrene-based resins, polyurethane-based resins, polysulfone-based resins, polyether-based resins, polyacrylonitrile-based resins, etc., can be used after being processed into film from their melt or solution. Among them, PET film is most preferably used in view of transparency, heat resistance, chemical resistance, cost, etc.

As such transparent substrates, it is possible to use a mono layer film or a laminate film of two layers or more consisting of single substance or a mixture of 2 kinds or more of these plastic films or the like, but preferably, a transparent substrate having a total light transmittance of 85% or more is better.

A thickness of such transparent substrate may be decided depending on its use and not especially limited. In cases where the electromagnetic wave shielding display of the present invention is used as a general optical filter, it is preferable to be 25 μm or more and further preferable to be 50 μm or more. On the other hand, the upper limit is preferably 250 μm or less and more preferably be 150 μm or less.

In order to provide a metal layer on such transparent substrate, a considerable strength is necessary for said transparent substrate, and for that, it is preferable to make its thickness to 25 μm or more. If the thickness is 50 μm or more, the bending strength further increases and it is preferable since its handling property during processing is improved. On the other hand, in cases where a PET film or the like of less than 50 μm is used as a transparent substrate, other films, for example, a PET film with an ultraviolet ray and/or infrared ray cut function or a PET film with a hard coat, or the like, may be laminated to increase the thickness.

Furthermore, the film as such transparent substrate is generally used by unwinding from a roll. For that reason, when the film thickness of a specified value or more, the film does not return to flat and may become to a curled condition, and a step for returning to flat becomes necessary. However, if the thickness is 250 μm or less, it is preferable since, without a specific step, said film can be used as it is. Furthermore, if the thickness is 150 μm or less, it is more preferable since, when it is made into a display, a sufficient brightness can easily be obtained, and it is not necessary to use a high cost substrate such as a highly transparent PET film as the transparent substrate.

Furthermore, the transparent substrate 1 may be, as required, subjected to a publicly known adhesion treatment such as corona discharge treatment, ozone blowing treatment, plasma treatment or highly adhesive primer coat treatment, while forming or after forming the transparent substrate 1. For example, in case of a PET film or the like, by using a commercially available highly adhesive film, it is also, possible to omit a further easy adhesion treatment.

The transparent electromagnetic wave shield member of the present invention is a member in which a metal layer of a network structure having a geometrical shape is formed on the transparent substrate. Whereas, the metal layer may be formed directly on the transparent substrate or, as stated later, a metal oxide layer may be formed between the transparent substrate and the metal layer.

As such metal layer 2, in which one kind or an alloy of two kinds or more of highly electroconductive metals such as platinum, gold, silver, copper, aluminum, nickel or iron can be used but, in view of stability of the obtained structure against external factors, platinum, gold, silver and copper are preferably used. Among these metals, in view of cost and electroconductivity, copper is most preferably used.

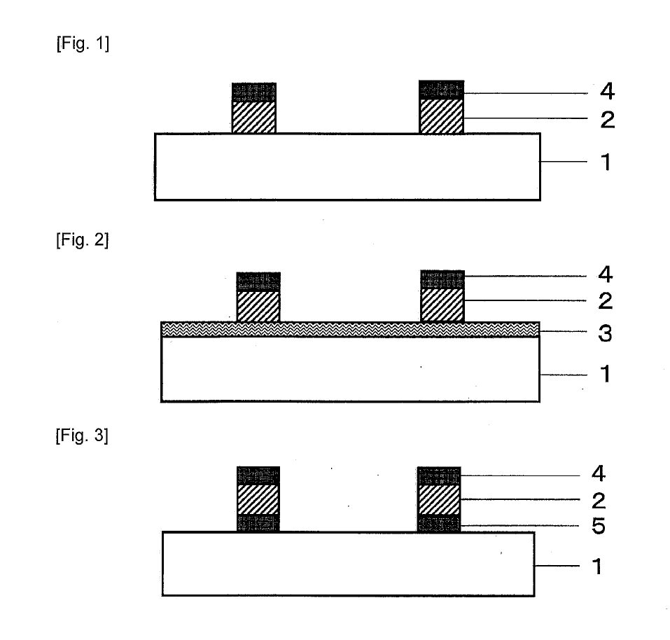

As method for forming such a metal layer on the transparent substrate, it is not especially limited such as any one method of dry processes including a method in which a metal foil is laminated via the adhesive layer 3 (hereafter, a metal foil lamination method), vacuum vapor deposition method, sputtering method, ion plating method or chemical vapor deposition method or wet processes including electroless and electroplating method, or a method in which two or more methods are combined. However, in cases where a metal foil lamination method is employed, since the metal layer is laminated via the adhesive layer, the adhesive may be deft in the opening portions after forming the network structure, to decrease transparency (e.g., FIG. 2). And, in the electroless plating or the electroplating method, it is necessary to form an electroconductive layer or a plating catalyst layer beforehand on the transparent substrate, and the process becomes complicated. In view of the above, as a process for forming the electroconductive metal layer on the transparent substrate, it is preferable to employ vacuum vapor deposition method, sputtering method, ion plating, chemical vapor deposition method (CVD) or the like. Furthermore, in view of close contactness of the metal film, electric characteristics, etc., it is more preferable to employ vacuum vapor deposition method or a sputtering method.

The metal layer 2 of the present invention is a layer having electroconductive properties provided on the transparent substrate and, as the surface resistance becomes lower (electroconductive properties is high), its electromagnetic wave shielding properties becomes more excellent. By the method mentioned later, a portion of the metal layer is removed, for example, by patterning into such as of lattice-like, it can be made into a metal layer of a network structure having a geometrical shape, and electromagnetic wave shielding properties and transparency which is necessary when it is fixed to a display can be made compatible.

As to kind of the metal layer 2, among metals such as copper, aluminum, nickel, iron, gold, silver, stainless steel, chromium or titanium, one kind or an alloy or a multilayered one in which two kinds or more are combined can be used. In view of electroconductive properties, easiness of patterning, cost, etc. for obtaining good electromagnetic wave shielding properties, copper and aluminum are preferable.

Furthermore, it is necessary that a thickness of the metal layer is 0.00001 μm or more and 2 μm or less. As the metal layer becomes thicker, the electromagnetic wave shielding properties becomes higher and it is preferable, but if the thickness exceeds 2 μm, a long time is needed to remove the metal and productivity lowers, or the transparent substrate itself is also heated at abrasion treatment and the transparent substrate is damaged to impair its surface smoothness and transparency. On the other hand, if the thickness of the metal layer is less than 0.00001 μm, shielding performance is not exhibited, and in both cases where a plating treatment is carried out or where an electroplating is carried out, electroconductivity is insufficient in cases where an electroplating is carried out, or the metal layer does not act also as a plating catalyst in cases where an electroless plating is carried out. The thickness of the metal layer is preferably 0.02 to 2 μm and more preferably 0.02 to 1 μm. It is preferable if the thickness of the metal layer is 0.1 μm or more, since sufficient electromagnetic wave shielding properties can be obtained.

The method for manufacturing the transparent electromagnetic wave shield member of the present invention comprises a step for providing a metal layer of a thickness of 2 μm or less and a step of removing the metal layer by a laser abrasion, but preferably comprises a step of forming a metal oxide layer on at least one surface side of the metal layer (e.g., FIG. 1 and FIG. 4). The first metal oxide layer 4 of the present invention is a layer provided on at least one surface side of the metal layer 2, and formed into a metal layer of a network structure having a patterned shape (geometrical shape) together with the metal layer 2 by the method mentioned later, and it prevents a decrease of visibility of displayed image caused by the metallic luster of the metal layer 2. It is preferable that a first metal oxide layer is provided on the surface side opposite to the surface of the transparent substrate 1 side of the metal layer 2. Thus, it is possible to reduce a decrease of visibility of a displayed image by providing the metal oxide layer on the viewer side layer when a display is placed.

As to the first metal oxide layer 4 of the present invention, its kind and forming method is not especially limited as far as it is possible to obtain an aimed reducing effect of visibility decrease of a displayed image when the transparent electromagnetic wave shield member is fixed to a display, but among metal oxides such as copper, aluminum, nickel, iron, gold, silver, stainless steel, chromium, titanium or tin, one kind or an alloy in which two kinds or more are combined is used. Among them, in view of price and film stability, oxide of copper, that is, copper oxide is preferable.

It is necessary that the thickness of the first metal oxide layer 4 is 0.01 to 0.1 μm. If the thickness is less than 0.01 μm, a sufficient reducing effect of the visibility decrease is not obtained, and even if the thickness exceeds 0.1 μm, it is not preferable since not only a sufficient reducing effect of the visibility decrease is not obtained, but also, in the step of forming into a patterned shape by removing a portion thereof, together with the metal layer 2, by the method mentioned later, the processing time becomes long or a viewing angle when fixed to a display becomes narrow. In view of these reducing effects of visibility decrease and processability, it is preferable that the thickness of the first metal oxide layer is 0.02 to 0.06 μm.

Method for forming the first metal oxide layer 4 is not especially limited to such as one method or a method combining 2 or more methods of the thin film forming techniques including vacuum vapor deposition method, sputtering method, ion plating method, chemical vapor deposition method, electroless and electroplating method, but vacuum vapor deposition method, sputtering method, ion plating method and chemical vapor deposition method are preferable in view of cost and easiness of manufacturing.

Furthermore, the first metal oxide layer 4 can be provided on either surface of the metal layer 2 as a separate layer from the metal layer 2 but, the present invention is not limited to that. For example, it can also be obtained by a method in which a portion of only the transparent substrate side or only the opposite side of the metal layer 2 is subjected to an oxidation treatment while forming the metal layer 2 or by a method in which, after forming the metal layer 2, its surface is subjected an oxidation or hydroxylation treatment.

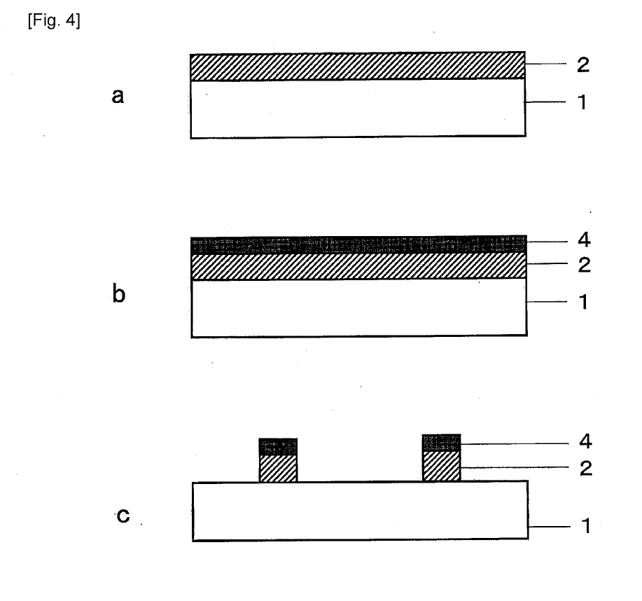

Furthermore, in the electromagnetic wave shield member of the present invention, it is preferable to provide the second metal oxide layer 5 on the opposite surface side to the surface side of the metal layer 2 on which the first metal oxide layer 4 is provided (e.g., FIG. 3). By providing the second metal oxide layer 5, not only reflection from a viewer side (external light or a fluorescent lamp is reflected by the metal layer) by metallic luster of the metal layer formed into a patterned shape (network structure having a geometrical shape) but also reflection from the display (an image from the display is reflected by the metal layer) can be reduced, and further, it is possible to reduce decrease of image visibility. It is preferable that the thickness of the second metal oxide layer is 0.01 to 0.1 μm. If the thickness is 0.01 μm or more, it is possible to reduce decrease of image visibility by metallic luster of the metal portion also from the display side. If the thickness is 0.1 μm or less, not only the decrease of image visibility by metallic luster of the metal layer can be reduced but also the processing time does not become long in the step of forming a patterned shape by removing a portion of the metal layer together with the first metal oxide layer. As a kind or a forming method of the second metal oxide layer 5, the same kind or forming method as those of the first metal oxide layer 4 can be used.

As a method for forming the metal layer of the present invention into a network structure having a geometrical shape (patterned shape), since fine lines of the network structure can be formed efficiently, and in addition, thickening of intersection portion of the copper network is small, it is preferable to carry out by laser abrasion method.

The laser abrasion is a phenomenon that, in cases where a laser light with high energy density is irradiated to surface of a solid which absorbs the laser light, intermolecular bonds of the irradiated portion are broken and vaporized and the surface of the irradiated solid is abraded. By using this phenomenon, it is possible to process surface of a solid. Since laser light is high in straight propagating and converging ability, it is possible to selectively process a minute area of about three times of wavelength of the laser light which is used for the abrasion and it is possible to obtain a high accuracy of processing by the laser abrasion method.

As a laser used for such an abrasion, any laser having a wavelength which is absorbed by the metal can be used. For example, it is possible to use solid lasers in which a gas laser, a semiconductor laser, an eximer laser or a semiconductor laser is used as an excitation light source. And, a second harmonic generation source (SHG), a third harmonic generation source (THG) or a fourth harmonic generation source (FHG) which can be obtained by combining these solid lasers and a non linear optical crystal can be used.

Among such solid lasers, in view of not processing the transparent substrate, it is preferable to use a UV laser of which wavelength is 204 nm to 533 nm. Among them, it is preferable to use a UV laser preferably of SHG (wavelength 533 nm) of solid lasers such as of Nd: YAG (neodium: yttrium.aluminum.garnet) or, more preferably THG (wavelength 355 nm) of solid lasers such as of Nd:YAG.

Among such gas lasers, it is also preferable to use an eximer laser. Among them, eximer lasers in which XeF (xenon fluoride), XeCl (xenon chloride) or KrF (krypton fluoride) is used, not only have wavelengths suitable for processing as their wavelengths are 351, 305 and 248 nm, respectively, but also, since their energy per pulse are high, are suitable for processing of a large area. In this case, a method in which the laser is irradiated to the metal layer through a mask of network structure having a geometrical shape (patterned shape) to be formed is desirable. A method in which a mask having a size of several times that of the shape to be made is prepared and projected in a reduced scale is desirable. As a mask to be used, in view of not absorbing laser energy, a method of forming a patterning on a chromium film formed on a quartz glass is employed, but any masks other than that can be used.

As an oscillation system of such a laser, a laser of any systems can be used, but in view of processing precision, it is desirable to use a pulse laser, and more desirable to use a pulls laser of its pulls width is ns or less.

Whereas, the network structure having a geometrical shape of the present invention denotes the figure formed by the metal layer which is present in the area, where light passes, of the finally obtainable electromagnetic wave shield sheet.

Shape of opening portion in the network structure having such a geometrical shape may be an arbitrary shape depending on display specification, for example, geometrical shapes such as triangles including equilateral triangle, isosceles triangle, right triangle, quadrilaterals including square, rectangle, rhombus, parallelogram, trapezoid and other polygons including hexagon, octagon, dodecagon, which are formed in straight line shapes, or circle, ellipse or other circular shapes formed in curved line shapes, can be exemplified, and in addition, combinations of those shapes can be exemplified. And, as to the shape of the opening portion, it is not necessary to be a uniform or periodical shape in all over the sheet, and may be constituted with opening portions which are different in respective sizes and shapes.

However, in view of easiness of forming a network structure of geometrical shape, an opening portion constituted with a straight line shape is preferable, and more preferably, it is a triangle or a quadrilateral.

Shape of the network structure having a geometrical shape finally formed in the electromagnetic wave shield member is not especially limited, as far as it is a shape which can secure conductivity to peripheral portion of the sheet, for example, geometrical figures can be exemplified.

It is necessary that an opening ratio of the network structure of the present invention is 84% or more. Here, the “opening ratio” in the present invention is the ratio of the area of the opening portion of the network with respect to the entire area of the transparent substrate, that is, ratio of the area which transmits light. As the opening ratio increases, total light transmittance increases and it becomes possible to manufacture an image displaying device having a high brightness and a good visibility. When the opening ratio is less than 84%, the total light transmittance becomes low and the image visibility becomes inferior. And when ratio of the network portion of the network structure increases, that is, line width of the network becomes thick, moirè phenomenon becomes easy to occur. And, the opening ratio is preferably 84 to 95%, more preferably in the range of 88 to 90%. When the opening ratio is 95% or less, the ratio of network portion is also not too small while total light transmittance is kept high, and it is preferable since good electromagnetic wave shielding properties are realized.

Here, determination method of the above-mentioned opening ratio of the network structure is explained. That is, a photograph observed by a microscope is converted into the black and white mode depending on its brightness distribution, and the opening ratio is calculated by dividing the area of opening portion by the entire area. This determination is repeated at 20 positions at random, and their average value is taken as the opening ratio.

Furthermore, it is necessary that spacing of such a network structure is 200 μm or less. The spacing of the network structure is preferably 150 μm or less, more preferably, 75 μm or less. When the spacing of the network structure becomes larger than 200 μm, a moirè becomes easy to generate. And, in case of a network structure in which the metal is arranged lattice-like, a fine line spacing of the metal, i.e., spacing of the network structure is an important factor for deciding shielding performance, and as this spacing becomes narrower, a more excellent shielding performance is exhibited. It is desirable that the spacing of network structure is finer, but in view of accuracy of processing, to be 40 μm or more is desirable.

Here, the “spacing of network structure” of the present invention is explained. At first, opening portion A of a network structure and a neighboring opening portion which share one side with this opening portion A are paid attention. Next, distances between the center of gravity of the opening portion A and centers of gravity of neighboring opening portions are measured. The shortest distance of the measured distances is taken as the spacing of network of the opening portion A. And, opening portion of 100 positions are arbitrarily selected from an electromagnetic wave shield member of 20 cm square, and the average value of the spacings of network of those opening portions is taken as the “spacing of network structure” of this electromagnetic wave shield member.

As to such a line width of network of the network structure, a desirable line width is determined from the above-mentioned network spacing and the opening ratio but, in order to secure a continuity of the pattern, it is preferable that the lower limit of line width is 3 μm or more. And, in order to achieve a sufficient image brightness in the display, it is preferable that the upper limit of such a line width of network is 12 μm or less. In addition, when the electromagnetic wave shielding properties and image qualities of display such as moirè prevention or non-visibility are considered, more preferably it is better to be 9 μm or less and most preferably 6 μm or less. Whereas, when a laser abrasion is employed, there is a merit that such a line width or network spacing can be changed easily.

In the present invention, in order to more enhance the electromagnetic wave shielding properties, it is preferable that the line of network of the metal layer is not broken and continuous in the final electromagnetic wave shield member.

Furthermore, the electromagnetic wave shield member may be covered at its peripheral portion with a frame such as of a display, when set in the display. In this case, the peripheral portion is a portion where no transparency is necessary. For that reason, in cases where it is covered by a frame, in the peripheral portion of the electromagnetic wave shield member, the shape of the opening portion and the opening ratio are not especially limited, and there may be no opening portion such that an earth can be fixed easily. Thus prepared electromagnetic wave shield member exhibits a sufficient shielding performance, but in cases where more excellent electromagnetic wave shielding properties are required, on the metal layer of the network structure processed by a laser, a plating treatment such as an electroplating or electroless plating by any known method may be carried out. As such a metal which constitutes the plated metal layer is not especially limited, but copper, nickel, chromium, zinc, gold, silver, aluminum, tin, platinum, palladium, cobalt, iron, indium or the like can be used, and one kind or a combination of two kinds or more of the metals can be used. Among them, in view of electroconductivity, electroplating properties, etc., it is preferable to use copper. And, in such a case, it is possible to carry out a treatment for improving visibility by changing the metal surface after the plating into black (the metal surface is oxidized) by any known blackening treatment.

The electromagnetic wave shield sheet of the present invention manufactured as above-mentioned is preferably used as a filter to be fixed to a plasma display or the like together with an antireflection layer.

The display is a device comprising, for example, a PDP, a filter, a power supply circuit, a circuit for converting from a video signal to an electric signal suitable for the PDP, etc., stored in one housing, and a relation of positions of the PDP and the filter is as stated later. Whereas, in the housing of the display, it is possible to store together a speaker to make a sound, a driving circuit for the speaker, a TV wave receiving circuit or the like.

The filter in which the electromagnetic wave shield member of the present invention is used is fixed to a PDP in either way of the following two configurations. One is a configuration in which the electromagnetic wave shield member is directly laminated to a front glass plate of the PDP and another is a configuration in which the electromagnetic wave shield member is laminated to a glass plate prepared separately and the laminated body is placed in front of the PDP with a small clearance. The electromagnetic wave shield member of the present invention is preferably used in the former configuration.

Constitutions of the filter are as follows, respectively, in the above-mentioned 2 configurations. In the former configuration, for example, it is, from the PDP side, a shock absorbing layer, the electromagnetic wave shield member (transparent substrate in PDP side), a color control layer, a near infrared ray cutting layer and an antireflection layer. In the latter configuration, it is the electromagnetic wave shield member (resin layer having a pattern in PDP side), a glass, a color control layer, a near infrared ray cutting layer, and an antireflection layer.

The above-mentioned layers having respective functions may be respectively separate layers or may be one layer which exhibits multiple functions. For these, although not limited thereto, materials having respectively the following constitutions or compositions can be used.

The antireflection layer comprises at least 2 layers of a low refractive index layer and a high refractive index layer, and the high refractive index layer is placed in PDP side. In order to form the low refractive index layer, a silane coupling agent or a fluoro resin having an alkoxysilyl group can be used. In order to form the high refractive index resin layer, an acryl-based resin containing a metal compound particle. It is preferable to use a metal compound particle together since an antistatic effect is obtained, and dust is prevented from depositing on the filter. The respective resins are dissolved in known organic solvents, and may be coated to an electromagnetic wave shield sheet or to a separately prepared substrate.

The near infrared ray cutting layer can be formed by coating a coloring matter having near infrared ray absorbability such as a diimonium-based compound to the transparent substrate of the electromagnetic wave shield sheet or to a substrate separately prepared. At this time, when a phthalocyanine-based compound, a cyanine-based compound or a dithiol nickel complex-based compound is used together, it is preferable since the absorbability can be enhanced.

The color control layer can be formed, for example, by coating a coloring matter which absorbs visible light near wavelength of 590 nm such as a porphyrazine-based compound to the transparent substrate of the electromagnetic wave shield sheet or to a substrate separately prepared. Whereas, said coloring matter may be used together with a coloring matter having near infrared ray absorbability, and coated to the substrate together with a polymer binder by using a known organic solvent.

### EXAMPLES

Evaluation methods of each example and comparative example are explained.

### (1) Line Width and Spacing (Pitch) of Network Structure

By using a digital microscope (VHX-200) produced by Keyence Corp., a surface observation was carried out at a magnification of 450 times. By using its length measuring function, a line width of lattice-like electroconductive pattern and a spacing (pitch) (spacing between confronting line widths) were measured. In each example•comparative example, from one sheet of 20 cm×20 cm size sample, in arbitrarily selected 25 positions (for each position, 4 fine lines and fine line spacing of 1 position), 100 line widths and spacings (pitch) of 25 positions in total were measured, and their average values were taken as respective sizes.

### (2) Opening Ratio of Network Structure

By using a digital microscope (VHX-200) produced by Keyence Corp., a surface observation was carried out at a magnification of 200 times. By using its brightness extraction function (histogram extraction, brightness range setting 0-170), the surface was converted into 2 values of a portion where no metal layer of the network structure is formed (opening portion) and a portion where a metal layer of the network structure is formed. Next, by using its area measuring function, an entire area, and an area of the opening portion were calculated and by dividing the area of the opening portion by the entire area, an opening ratio was obtained. In each example•comparative example, from one sheet of 20 cm×20 cm size sample, for arbitrarily selected 20 positions, opening ratios were calculated, and its average value was taken as the opening ratio.

### (3) Thicknesses of Metal Layer and Metal Oxide Layer

By FIB (focused ion beam) micro sampling system (FB-2000A produced by Hitachi, Ltd.), a sample cross-section was cut out, the cross-section was observed by a transmission electron microscope (H-9000UHRII produced by Hitachi, Ltd., acceleration voltage 300 kV, observation magnification of 200,000 times), thicknesses of a metal layer and a metal oxide layer of less than 0.1 μm were measured. In each example•comparative example, from one sheet of 20 cm×20 cm size sample, for arbitrarily selected 3 positions, thicknesses were measured, and their average value was taken as the thickness of the metal oxide layer.

Furthermore, as to thicknesses of a metal layer and a metal/metal oxide layer of 0.1 μm or more, by using a surface profile microscope (VF-7500) produced by Keyence Corp., a surface profile measurement was carried out at a magnification of 2500 times and thickness of a fine line of the network structure was measured. From one sheet of 20 cm×20 cm size sample, for arbitrarily selected 20 positions, thicknesses were measured, and their average value was taken as the thickness of the metal layer of the sample.

### (4) Electromagnetic Wave Shielding Properties

By using a spectrum analyzer system (shield evaluation instrument TR17031A) produced by Advantest Corp., and by KEC (Kansai Electronic Industry Development Center) method, a damping of electric field wave (dB) in the frequency range of 1 MHz to 1 GHz was measured, and evaluated by the following criteria. In each example comparative example, measurements were carried out for 3 samples.

Damping of electric field wave at frequency 50 MHz: 40 dB or more in all of 3 sheets . . . o
Damping of electric field wave at frequency 50 MHz: less than 40 dB in at least one sheet . . . x

As the value of damping of electric field wave (dB) increases more, the electromagnetic wave shielding properties becomes more excellent. “o” denotes to be of a good electromagnetic wave shielding properties.

### (5) Image Visibility (Visibility of Display Picture)

A transparent electromagnetic wave shield member was laminated to the outermost surface of a PDP (plasma display panel) picture, a visual observation was carried our from directions of the front, up and down, and right and left, and image visibility was evaluated by the following criteria. In each example•comparative example, measurements were carried out for 3 sheets of sample. And, the visual observation was carried out by one person.

No unevenness or glaring in picture is generated in all of 3 sheets . . . o
An unevenness or glaring in picture is generated in 1 or 2 sheets . . . Δ
An unevenness or glaring in picture was generated in all of 3 sheets . . . x
“o” denotes that there is no decrease of image visibility and a good visibility is exhibited.

Whereas, the evaluation of image visibility was carried out by observing from the opposite side of the transparent substrate (the transparent substrate side was laminated to outermost surface of PDP picture and the evaluation was carried out by making the opposite side to the transparent substrate into visual inspection side.).

Furthermore, in cases where the transparent electromagnetic wave shield member has a metal oxide layer, the observation was carried out from the metal oxide layer side (in cases where the metal oxide layer is present on the opposite side of the transparent substrate, the observation evaluation was carried out by making the opposite side of the transparent substrate into visual inspection side. On the other hand, in cases where the metal oxide layer is present on the transparent substrate side, the observation evaluation was carried out by making the transparent substrate side into visual inspection side. And, in cases where 2 metal oxide layers are present on the transparent substrate side and the opposite side to the transparent substrate and, both evaluations were also carried out from the opposite side of the transparent substrate side and from the transparent substrate side.).

### (6) Laser Processability

It was decided by visual inspection whether or not a transparency is impaired by turning a transparent substrate into white turbid due to the heat generated at patterning by laser abrasion. The evaluation criteria are as follows. In each example•comparative example, measurements were carried out for 3 samples. And, the visual observation was carried out by one person.

There is no white turbidity of transparent substrate in all of 3 sheets . . . o
There is a white turbidity of transparent substrate at least 1 sheet . . . x
“o” denotes that there is no influence of heat at laser processing, and a good transparency is exhibited.
(7) Moirè

A prepared electromagnetic wave shield member was rotated 90° while closely contacting to a plasma TV (VIERA (trademark) PX50 produced by Matsushita Electric Industrial Co., Ltd.) to evaluate easiness of generation of a moirè. Those of which angle range in which a moirè is not visually observed was 60° or more were taken as o (good: moirè is hard to generate), those of less than 60° and 40° or more were taken as Δ (medium: moirè is a little easy to generate), those of less than 40° were taken as x (bad: moirè is easy to generate). And, a case where the evaluation is impossible for other reason was taken as “-”. Whereas, in each example•comparative example, measurements were carried out for 3 samples, and a moirè evaluation of each example•comparative example was made based on the following criteria.

o (good: moirè is hard to generate): evaluation results of 3 sheets are all “o”.
Δ (medium: moirè is a little easy to generate): There is no sample of its evaluation result is “x” or “-”, but evaluation of at least 1 sheet of sample is “Δ”.
x (bad: moirè is easy to generate): there is no sample of its evaluation result is “-”, but evaluation result of at least 1 sheet of sample is “x”.
-(measurement is impossible): at least 1 sheet of sample is impossible to be measured.

In the following each example•comparative example, the direction in which a transparent substrate is present in respect to a metal layer is referred to as “transparent substrate side”, and the opposite direction is referred to as “the opposite side of the transparent substrate”. In cases where a processing method other than a laser was employed is shown as “-”.

Furthermore, as to preparation method of a metal oxide layer, in cases where it is prepared by sputtering method (degree of vacuum: 0.5 Pa, target: copper, introduced gas ratio: oxygen 100%), it was described as “sputter”, and in case of black oxide treating agent produced by Meltex Inc. (Enplate MB-438A/B produced by Meltex Inc. is adjusted to a ratio of A/B/pure water=8/13/79), it was described as “wet”.

### Example 1

By sputtering copper (degree of vacuum: 0.5 Pa, target: copper, introduced gas ratio: Argon 100%) on one surface of a PET film (Lumirror (trademark) U34 produced by Toray Industries, Inc.) of a thickness 100 μm, a film was prepared in which a copper layer of a thickness 0.08 μm was formed on the PET.

Next, by sputtering method (degree of vacuum: 0.5 Pa, target: copper, introduced gas ratio: oxygen 100%), copper oxide of a thickness 0.05 μm was formed on the copper (the first metal oxide layer).

By irradiating the third harmonic of YAG laser of wavelength 355 nm to the opposite side to the transparent substrate (sputtering surface) of the film, a transparent electromagnetic wave shield member was prepared in which a network structure having a line width of 5 μm and a network structure spacing of 75 μm, based on a structure in which only a copper layer in square portion of one side 70 μm was abraded, was formed on the surface.

As shown in Table 1, the visibility, electromagnetic wave shielding properties and moirè were all good.

### Example 2

After carrying out a vacuum vapor deposition (degree of vacuum: 3×10⁻³ Pa) of copper of only a thickness of 0.3 μm on the same PET film as that of Example 1, by further sputtering copper oxide of only a thickness 0.03 μm, a film in which a metal layer of a thickness 0.33 μm is formed on the PET was prepared.

By irradiating the third harmonic of YAG laser of wavelength 355 nm to the opposite side to the transparent substrate (the metal layer formed surface) of the prepared film, a transparent electromagnetic wave shield member was prepared in which a network structure having a line width of 5 μm and a network structure spacing of 75 μm, based on a structure in which only a copper layer in square portion of one side 70 μm was abraded, was formed on the surface.

As shown in Table 1, the visibility, electromagnetic wave shielding properties and moirè were all good.

### Example 3

In the same way as Example 2, after carrying out a vacuum vapor deposition of copper of only a thickness of 0.5 μm on the PET film, by further sputtering copper oxide of only a thickness 0.03 μm, a film in which a metal layer of a thickness 0.53 μm is formed on the PET, was prepared.

By irradiating the third harmonic of YAG laser of wavelength 355 nm to the opposite side to the transparent substrate (the metal layer formed surface) of the prepared film, a transparent electromagnetic wave shield member was prepared in which a network structure having a line width of 8 μm and a network structure spacing of 150 μm, based on a structure in which only a copper layer in square portion of one side 142 μm was abraded, was formed on the surface.

As shown in Table 1, the visibility, electromagnetic wave shielding properties and moirè were all good.

### Example 4

By sputtering copper (degree of vacuum: 0.5 Pa, target: copper, introduced gas ratio: Argon 100%) on the same PET film as that of Example 1, a film in which copper layer of a thickness 0.04 μm is formed on the PET was prepared.

By irradiating KrF eximer laser of wavelength 248 nm to the opposite side to the transparent substrate (the sputtering surface) of the prepared film, a film was prepared in which a network structure having a line width of 6 μm and a network structure spacing of 150 μm, based on a structure in which only the metal layer in square portion of one side 144 μm was abraded, was formed on the surface.

This film was immersed in the following electrolytic copper plating solution, passed a current of 0.3 A to 100 cm² of the film to carry out an electrolytic copper plating for 5 minutes, and made the copper layer into a thickness of 2.0 μm. After that, the film was taken out, and after washed with water, the film was dried to vaporize water component at 120° C. for 1 minute.

The prepared film was subjected to an immersion treatment in an oxidation treatment agent (Enplate MB-438A/B produced by Meltex Inc. prepared in a ratio of A/B/pure water=8/13/79) at 60° C. for 5 min (black oxide treatment of metal surface).

The final network structure after the copper plating was, line width 10 μm, thickness 2.0 μm (thickness of the metal oxide layer: 0.2 μm, thickness of the metal layer: 1.8 μm), and spacing of network structure 150 μm.

As shown in Table 1, the visibility, electromagnetic wave shielding properties and moirè were all good.

Electrolytic copper plating solution: 6 L of copper sulfate solution SG (produced by Meltex Inc.) was added to 7 L water and stirred. Next, after 97% sulfuric acid (sulfuric acid 97% produced by Ishizu Pharmaceutical, Co., guaranteed reagent) of 2.1 L was added, 1N hydrochloric acid (N/1-hydrochloric acid produced by Nacarai Tesuque, Inc.) of 28 mL was added. Furthermore, to this solution, each 100 mL of Copper Gleam CLX-A and CLX-C produced by Rohm and Haas Electronic Materials Co. was added in this order as brighteners for copper sulfate plating, and finally, water was added to make the entire solution to 20 L.

### Example 5

On the same PET film as that of Example 1, by a sputtering method (degree of vacuum: 0.5 Pa, target: copper, introduced gas ratio: oxygen 100%), copper oxide of a thickness 0.04 μm was formed (the first metal oxide layer).

Next, by a sputtering method (degree of vacuum: 0.5 Pa, target: copper, introduced gas ratio: Argon 100%), copper of a thickness 0.2 μm was formed on the copper oxide (metal layer).

Furthermore, by a sputtering method (degree of vacuum: 0.5 Pa, target: copper, introduced gas ratio: oxygen 100%), copper oxide of a thickness 0.1 μm was formed on the copper (the second metal oxide layer).

To the opposite side to the transparent substrate of the prepared film (copper oxide/copper/copper oxide surface side), the third harmonic of Nd: YAG laser of wavelength 355 nm was irradiated to obtain a transparent electromagnetic wave shield member of a lattice-like electroconductive pattern having a line width 10 μm, spacing (pitch) 150 μm and an opening ratio 87%. Whereas, as to the image visibility, it was evaluated by observing from both of the transparent substrate side and the opposite side to the transparent substrate.

As shown in Table 1, the visibility, electromagnetic wave shielding properties and moirè were all good.

### Example 6

The sample of Example 5 was sputtered such that the copper oxide of the opposite side to the transparent substrate (thickness 0.1 μm) would be the first metal oxide layer (sputtered such that the copper oxide of the second metal oxide layer of Example 5 would be the first metal oxide layer of Example 6), and sputtered such that the copper oxide of the transparent substrate side (the thickness 0.04 μm) would be the second metal oxide layer (sputtered such that the copper oxide of the first metal oxide layer of Example 5 would be the second metal oxide layer of Example 6), and after that, it was processed in the same way as Example 5, to obtain a transparent electromagnetic wave shield member.

It was evaluated in the same way as Example 1. Whereas, as to the image visibility, it was evaluated by observing from both of the transparent substrate side and the opposite side to the transparent substrate. As shown in Table 1, the visibility, electromagnetic wave shielding properties and moirè were all good.

### Example 7

By sputtering copper (degree of vacuum: 0.5 Pa, target: copper, introduced gas ratio: Argon 100%) to one surface of a PET film of a thickness 100 μm (Lumirror (trademark) U34 produced by Toray Industries, Inc.), a film in which a copper layer of a thickness 0.08 μm was formed on the PET was prepared.

By irradiating the third harmonic of YAG laser of wavelength 355 nm to the opposite side to the transparent substrate (sputtering surface) of the film, a transparent electromagnetic wave shield member was prepared in which a network structure having a line width of 5 μm and a network structure spacing of 75 μm, based on a structure in which only a copper layer in square portion of one side 70 μm was abraded, was formed on the surface.

As shown in Table 1, although the visibility was inferior, both of the electromagnetic wave shielding properties and the moirè were good.

### Example 8

In the same way as Example 2, copper was vacuum vapor deposited (degree of vacuum: 3×10⁻³ Pa) only in a thickness of 0.3 μm on the PET film (only the copper layer was formed, and a metal oxide layer was not formed.).

By irradiating the third harmonic of YAG laser of wavelength 355 nm to the opposite side to the transparent substrate (the metal layer formed surface) of the prepared film, a transparent electromagnetic wave shield member was prepared in which a network structure having a line width of 5 μm and a network structure spacing of 75 μm, based on a structure in which only a copper layer in square portion of one side 70 μm was abraded, was formed on the surface.

As shown in Table 1, although the visibility was inferior, both of the electromagnetic wave shielding properties and the moirè were good.

### Example 9

In the same way as Example 2, copper was vacuum vapor deposited only in a thickness of 0.5 μm on the PET film (only the copper layer was formed, and a metal oxide layer was not formed.).

By irradiating the third harmonic of YAG laser of wavelength 355 nm to the opposite side to the transparent substrate (the metal layer formed surface) of the prepared film, a transparent electromagnetic wave shield member was prepared in which a network structure having a line width of 8 μm and a network structure spacing of 150 μm, based on a structure in which only a copper layer in square portion of one side 142 μm was abraded, was formed on the surface.

As shown in Table 1, although the visibility was inferior, both of the electromagnetic wave shielding properties and the moirè were good.

### Example 10

By sputtering copper (degree of vacuum: 0.5 Pa, target: copper, introduced gas ratio: Argon 100%) on the same PET film as that of Example 1, a film was prepared in which a copper layer of a thickness 0.04 μm was formed on the PET (only the copper layer was formed, and a metal oxide layer was not formed.).

By irradiating KrF eximer laser of wavelength 248 nm to the opposite side to the transparent substrate (the sputtering surface) of the prepared film, a film was prepared in which a network structure having a line width of 6 μm and a network structure spacing of 150 μm, based on a structure in which only the metal layer in square portion of one side 144 μm was abraded, was formed on the surface.

This film was immersed in the following electrolytic copper plating solution, and passed a current of 0.3 A per 100 cm² of the film to carry out an electrolytic copper plating for 5 minutes (thickness of the copper layer was 2.0 μm, spacing of the network structure was 10 μm.). After that, the film was taken out, and after washed with water, the film was dried to vaporize water component at 120° C. for 1 minute.

As shown in Table 1, although the visibility was inferior, both of the electromagnetic wave shielding properties and the moirè were good.

Electrolytic copper plating solution: 6 L of copper sulfate solution SG (produced by Meltex Inc.) was added to 7 L water and stirred. Next, after 97% sulfuric acid (sulfuric acid 97% produced by Ishizu Chemicals, Co., guaranteed reagent) of 2.1 L was added, 1N hydrochloric acid (N/1-hydrochloric acid produced by Nacarai Tesuque, Inc.) of 28 mL was added. Furthermore, to this solution, each 100 mL of Copper Gleam CLX-A and CLX-C produced by Rohm and Haas Electronic Materials Co. was added in this order as brighteners for copper sulfate plating, and finally, water was added to make the entire solution to 20 L.

### Comparative Example 1

By irradiating the third harmonic of YAG laser of wavelength 355 nm to the opposite side to the transparent substrate (copper-deposited surface) of a film on which a copper layer and a copper oxide were prepared in the same method as Example 1, a transparent electromagnetic wave shield member was prepared in which a copper network structure having a line width of 20 μm and a network structure spacing of 250 μm, based on a structure in which only a copper layer in square portion of one side 230 μm was abraded, was formed on the surface.

As shown in Table 1, in the method shown in this comparative example, since the spacing of network structure was wide as more than 200 μm, although the visibility was good, it was confirmed that a good shielding performance could not be exhibited. And, frequency of moirè generation was also high.

### Comparative Example 2

To a PET film of a thickness 100 μm (Lumirror (trademark) U34 produced by Toray Industries, Inc.), 12 μm electrolytic copper foil (SQ-VLP, Mitsui Kinzoku) was put by a lamination treatment, to prepare a laminate film of PET and copper.

On surface of the opposite side to the transparent substrate (copper side) of the obtained film, a network pattern of line width 25 μm and 150 μm spacing, (pitch) was printed by a waterless printing plate method. As the ink, a UV curable ink (Bestcure (trademark) UV171 black ink produced by T&K Toka Co.) was used and after the printing, a transparent electromagnetic wave shield film was prepared by an etching with a ferric chloride solution.

The prepared line width of the network was 20 μm. Although the film prepared by the etching method had a sufficient shielding performance, the line width or the intersection was thick and a sufficient opening ratio could not be obtained. For that reason, a sufficient visibility as a PDP display filter could not be obtained.

### Comparative Example 3

To a PET film of a thickness 100 μm (Lumirror (trademark) U34 produced by Toray Industries, Inc.), 12 μm electrolytic copper foil (SQ-VLP, Mitsui Kinzoku) was put by a lamination treatment, to prepare a laminate film of PET and copper.

On surface of the opposite side to the transparent substrate (copper side surface) of the obtained film, a network pattern of line width 25 μm and 300 μm spacing (pitch) was printed by a waterless printing plate method. As the ink, a UV curable ink (Bestcure (trademark) UV171 black ink produced by T&K Toka Co.) was used and after the printing, a transparent electromagnetic wave shield film was prepared by an etching with a ferric chloride solution.

The line width after the etching was 20 μm. Although the film prepared by the etching method had a sufficient shielding performance, since the spacing of network structure was high as 300 μm, frequency of moirè generation was high and it was difficult to secure a good visibility as a PDP display.

### Comparative Example 4

After copper was vacuum vapor deposited only in a thickness of 2.5 μm on the same PET film as that of Example 1 (degree of vacuum: 3×10⁻³ Pa), by irradiating the third harmonic of YAG laser of wavelength 355 nm to the opposite side to the transparent substrate (copper-deposited surface) of the prepared film, a transparent electromagnetic wave shield member was prepared in which a network structure having a line width of 8 μm and a network structure spacing of 150 μm, based on a structure in which only a copper layer in square portion of one side 142 μm was abraded, was formed on the surface.

Although the shielding performance was good, since the film thickness was thick as 2 μm or more, the PET film of the substrate was deformed and discolored and it was difficult to secure a good visibility due to a thermal damage at the abrasion. For that reason, it was difficult to confirm a generation of moirè.

### Example 11

A copper oxide layer of a thickness 0.15 μm was formed by a sputtering method (degree of vacuum: 0.5 Pa, target: copper, introduced gas ratio: Oxygen 100%) on a PET film of a thickness 100 μm (Lumirror (trademark) U34 produced by Toray Industries, Inc.) (the first metal oxide layer).

Next, by a vacuum vapor deposition method by resistance heating (degree of vacuum: 3×10⁻³ Pa), a copper vapor deposition was carried out to form copper of a thickness 0.3 μm on the copper oxide layer (metal layer).

To the opposite side to the transparent substrate (the copper oxide/copper surface side) of the prepared film, the third harmonic of Nd:YAG laser of wavelength 355 nm was irradiated and a transparent electromagnetic wave shield member of a lattice-like electroconductive pattern having a line width of 10 μm, a spacing (pitch) of 150 μm and an opening ratio of 87% was obtained.

From the obtained transparent electromagnetic wave shield member, a sample of 20 cm×20 cm size was cut out, and evaluated in the same way as Example 1. Whereas, as to the image visibility, it was evaluated by observing from the transparent substrate side. Although the electromagnetic wave shielding properties, moirè and laser processability were good, the image visibility was low, but it was a level of no problem.

### Example 12

On a PET film of thickness 100 μm (Lumirror (trademark) U34 produced by Toray Industries, Inc.), a copper oxide layer of a thickness of 0.11 μm was formed (the second metal oxide layer) by a sputtering method (degree of vacuum: 0.5 Pa, target: copper, introduced gas ratio: oxygen 100%).

Next, by a sputtering method (degree of vacuum: 0.5 Pa, target: copper, introduced gas ratio: Argon 100%), a copper of a thickness 0.3 μm was formed on the copper oxide (metal layer).

Furthermore, by a sputtering method (degree of vacuum: 0.5 Pa, target: copper, introduced gas ratio: oxygen 100%), a copper oxide of a thickness 0.005 μm was formed on the copper (the first metal oxide layer).

To the opposite side to the transparent substrate (the copper oxide/copper/copper oxide surface side) of the prepared film, the third harmonic of Nd:YAG laser of wavelength 355 nm was irradiated and a transparent electromagnetic wave shield member of a lattice-like electroconductive pattern having a line width of 10 μm, a spacing (pitch) of 150 μm and an opening ratio of 87% was obtained.

From the obtained transparent electromagnetic wave shield member, a sample of 20 cm×20 cm size was cut out, and evaluated in the same way as Example 1. Whereas, as to the image visibility, it was evaluated by observing from both of the transparent substrate side and the opposite side to the transparent substrate. Although the electromagnetic wave shielding properties, moirè and laser processability were good, the image visibility was low, but it was a level of no problem.

### Example 13

As to the sample of Example 12, a sputtering was carried out such that the copper oxide of the transparent substrate side of Example 12 (thickness 0.11 μm) would be the first metal oxide layer of Example 13 (the same film as the copper oxide of the transparent substrate of Example 12 was formed as a film of copper oxide of the opposite side to the transparent substrate of Example 13.), and a sputtering was carried out such that the copper oxide of the opposite side to the transparent substrate of Example 12 (thickness 0.005 μm) would be the second metal oxide layer of Example 13 (the same film as the copper oxide of the opposite side to the transparent substrate of Example 12 was formed as a film of copper oxide of the transparent substrate side of Example 13.), and evaluated in the same way as Example 1. Whereas, as to the image visibility, it was evaluated by observing from both of the transparent substrate side and the opposite side to the transparent substrate. Although the electromagnetic wave shielding properties, moirè and laser processability were good, the image visibility was low, but it was a level of no problem.

### Example 14

On a PET film of a thickness 100 μm (“Lumirror” (trademark) U34 produced by Toray Industries, Inc.), by a sputtering method (degree of vacuum: 0.5 Pa, target: copper, introduced gas ratio: oxygen 100%), a copper oxide of a thickness 0.005 μm was formed (the first metal oxide layer).

Next, by a vacuum vapor deposition method by resistance heating (degree of vacuum: 3×10⁻³ Pa), a copper vapor deposition was carried out to form a copper of a thickness 0.3 μm on the copper oxide layer (metal layer).

To the film copper oxide/copper surface side of the prepared film, the third harmonic of Nd:YAG laser of wavelength 355 nm was irradiated and a transparent electromagnetic wave shield member of a lattice-like electroconductive pattern having a line width of 10 μm, a spacing (pitch) of 150 μm and an opening ratio of 87% was obtained.

From the obtained transparent electromagnetic wave shield member, a sample of 20 cm×20 cm size was cut out, and evaluated in the same way as Example 1. Whereas, as to the image visibility, it was evaluated by observing from the transparent substrate side. Although the electromagnetic wave shielding properties, moirè and laser processability were good, the image visibility was low, but it was a level of no problem.

TABLE 1

| Item | | Ex. 1 | Ex. 2 | Ex. 3 | Ex. 4 | Ex. 5 | Ex. 6 | Ex. 7 | Ex. 8 | Ex. 9 | Ex. 10 |
|---|---|---|---|---|---|---|---|---|---|---|---|
| Transparent | Material | PET | PET | PET | PET | PET | PET | PET | PET | PET | PET |
| substrate | Thickness (μm) | 100 | 100 | 100 | 100 | 100 | 100 | 100 | 100 | 100 | 100 |
| Metal layer* | Material | copper | copper | copper | copper | copper | copper | copper | copper | copper | copper |
| | Thickness (μm) | 0.08 | 0.3 | 0.5 | 0.04 (1.8) | 0.2 | 0.2 | 0.08 | 0.3 | 0.5 | 0.04 (2.0) |
| The first metal | Material | copper oxide | | | | | | — | — | — | — |
| oxide layer | Surface formed | opposite side to transparent substrate | | | | transparent | | — | — | — | — |
| | | | | | | substrate side | | | | | |
| | Forming method | sputter | sputter | sputter | wet | sputter | sputter | — | — | — | — |
| | Thickness (μm) | 0.05 | 0.03 | 0.03 | 0.2 | 0.04 | 0.1 | — | — | — | — |
| The second metal | Material | — | — | — | — | copper | copper | — | — | — | — |
| oxide layer | | | | | | oxide | oxide | | | | |
| | Surface formed | — | — | — | — | opposite side to | | — | — | — | — |
| | | | | | | transparent | | | | | |
| | | | | | | substrate | | | | | |
| | Forming method | — | — | — | — | sputter | sputter | — | — | — | — |
| | Thickness (μm) | — | — | — | — | 0.1 | 0.04 | — | — | — | — |
| Electroconductive | Line width (μm) | 5 | 5 | 8 | 10 | 10 | 10 | 5 | 5 | 8 | 10 |
| pattern size | Spacing (pitch) (μm) | 75 | 75 | 150 | 150 | 150 | 150 | 75 | 75 | 150 | 150 |
| | Opening ratio (%) | 87 | 87 | 90 | 87 | 87 | 87 | 87 | 87 | 90 | 87 |
| Characteristics | Image visibility** | ∘ | ∘ | ∘ | ∘ | ∘ (∘) | ∘ (∘) | Δ | Δ | Δ | Δ |
| | Moiré | ∘ | ∘ | ∘ | ∘ | ∘ | ∘ | ∘ | ∘ | ∘ | ∘ |
| | Electromagnetic wave | ∘ | ∘ | ∘ | ∘ | ∘ | ∘ | ∘ | ∘ | ∘ | ∘ |
| | shielding properties | | | | | | | | | | |
| | Laser processability | ∘ | ∘ | ∘ | ∘ | ∘ | ∘ | ∘ | ∘ | ∘ | ∘ |

| Item | | Comp. ex. 1 | Comp. ex. 2 | Comp. ex. 3 | Comp. ex. 4 | Ex. 11 | Ex. 12 | Ex. 13 | Ex. 14 |
|---|---|---|---|---|---|---|---|---|---|
| Transparent | Material | PET | PET | PET | PET | PET | PET | PET | PET |
| substrate | Thickness (μm) | 100 | 100 | 100 | 100 | 100 | 100 | 100 | 100 |
| Metal layer* | Material | copper | copper | copper | copper | copper | copper | copper | copper |
| | Thickness (μm) | 0.08 | 12 | 12 | 2.5 | 0.3 | 0.3 | 0.3 | 0.3 |
| First metal | Material | copper oxide | — | — | — | copper oxide | | | |
| oxide layer | Surface formed | opposite side to | — | — | — | transparent | opposite side to | | transparent |
| | | transparent | | | | substrate side | transparent | | substrate side |
| | | substrate | | | | | substrate | | |
| | Forming method | sputter | — | — | — | sputter | sputter | sputter | sputter |
| | Thickness (μm) | 0.05 | — | — | — | 0.15 | 0.005 | 0.11 | 0.005 |
| Second metal | Material | — | — | — | — | — | copper oxide | | — |
| oxide layer | Surface formed | — | — | — | — | — | transparent | | — |
| | | | | | | | substrate side | | |
| | Forming method | — | — | — | — | — | sputter | sputter | — |
| | Thickness (μm) | — | — | — | — | — | 0.11 | 0.005 | — |
| Electro- | Line width (μm) | 20 | 20 | 20 | 8 | 10 | 10 | 10 | 10 |
| conductive | Spacing (pitch) | 250 | 150 | 300 | 150 | 150 | 150 | 150 | 150 |
| pattern size | (μm) | | | | | | | | |
| | An opening ratio | 85 | 74 | 87 | 90 | 87 | 87 | 87 | 87 |
| | (%) | | | | | | | | |
| Characteristics | Image visibility** | ∘ | x | x | — | (Δ) | Δ (Δ) | Δ (Δ) | (Δ) |
| | Moiré | x | Δ | x | — | ∘ | ∘ | ∘ | ∘ |
| | Electromagnetic | x | ∘ | ∘ | — | ∘ | ∘ | ∘ | ∘ |
| | wave shielding | | | | | | | | |
| | properties | | | | | | | | |
| | Laser | ∘ | — | — | x | ∘ | ∘ | ∘ | ∘ |
| | processability | | | | | | | | |

*The numerals in the bracket denote thickness of copper layer formed by plating
**In the brackets, evaluations visually inspected from transparent substrate side are shown.

### INDUSTRIAL APPLICABILITY

The present invention aims to provide a transparent electromagnetic wave shield member in which generation of a moirè phenomenon is more prevented compared to the prior art and an excellent electromagnetic wave shielding properties and a sufficient total light transmittance based on an appropriate network structure are compatible, and in addition, which does not impair visibility when fixed to a display, and a method for manufacturing the same.

1. A method for manufacturing a transparent electromagnetic wave shield member in which a metal layer of a network structure having a geometrical shape is formed on a transparent substrate,
which is a method for manufacturing a transparent electromagnetic wave shield member comprising a step for providing a metal layer of a thickness of 2 μm or less, a step for removing said metal layer by laser abrasion,
to form a metal layer of a network structure having a spacing of the network structure of 200 μm or less, and in addition, an opening ratio of the network structure of 84% or more.

2. A method for manufacturing a transparent electromagnetic wave shield member according to claim 1, wherein means for providing a metal layer on the above-mentioned transparent substrate is at least one kind dry film forming process selected from sputtering, vapor deposition, CVD and ion plating.

3. A method for manufacturing a transparent electromagnetic wave shield member according to claim 1, comprising a step of forming a metal oxide layer on at least one surface side of the metal layer.

4. A method for manufacturing a transparent electromagnetic wave shield member according to claim 3, wherein means for forming the above-mentioned metal oxide layer is at least one kind dry film forming process selected from sputtering, vapor deposition, CVD and ion plating.

5. A method for manufacturing a transparent electromagnetic wave shield member according to claim 1, wherein means for carrying out the above-mentioned laser abrasion is UV laser.

6. A method for manufacturing a transparent electromagnetic wave shield member according to claim 1, comprising plating the transparent electromagnetic wave shield member after the above-mentioned laser abrasion processing.

7. A transparent electromagnetic wave shield member in which a metal layer of a network structure having a geometrical shape is formed on a transparent substrate,
which is a transparent electromagnetic wave shield member of which spacing of a network structure is 200 μm or less, an opening ratio of the network structure is 84% or more, and in addition, a thickness of metal layer is 2 μm or less.

8. A transparent electromagnetic wave shield member according to claim 7, comprising a metal layer formed in a network structure having a geometrical shape on a transparent substrate and a first metal oxide layer of a thickness of 0.01 to 0.1 μm provided on at least one surface side of the metal layer.

9. A transparent electromagnetic wave shield member according to claim 8, wherein a thickness of the above-mentioned first metal oxide layer is 0.02 to 0.06 μm.

10. A transparent electromagnetic wave shield member according to claim 8, wherein the above-mentioned first metal oxide layer is copper oxide.

11. A transparent electromagnetic wave shield member according to claim 8, wherein the above-mentioned first metal oxide layer is provided on the opposite surface side to the above-mentioned transparent substrate side surface of the above-mentioned metal layer.

12. A transparent electromagnetic wave shield member according to claim 8, wherein the second metal oxide layer is provided on the opposite surface side to the surface side on which the above-mentioned first metal oxide layer is provided.

13. A transparent electromagnetic wave shield member according to claim 12, wherein the above-mentioned second metal oxide layer is copper oxide.

14. A filter provided with a transparent electromagnetic wave shield member described in claim 7 and an antireflection layer.

15. A display provided with a filter described in claim 14.
